(19) United States
(12) Patent Application Publication
(10) Pub. No.: US 2026/0106609 A1
(43) Pub. Date: Apr. 16, 2026

(54) Low-Side Switch Circuit, Method for Controlling the Same, Integrated Circuit, and Electronic Device

(71) Applicant: Halo Microelectronics (Beijing) Ltd., Beijing (CN)

(72) Inventors: Wenchao Qu, Chengdu (CN); Dongyang Xie, Beijing (CN); Bonan Lei, Beijing (CN)

(21) Appl. No.: 19/047,313

(22) Filed: Feb. 6, 2025

(30) Foreign Application Priority Data
Oct. 12, 2024 (CN) 202411426128.4

(51) Int. Cl. H03K 17/082

(52) U.S. Cl. CPC H03K 17/0822; H03K 2217/0072

(57) ABSTRACT

The present application discloses a low-side switch circuit and its control method, a low-side switch integrated circuit, and an electronic device. The low-side switch circuit comprises a switch transistor, and a first pull-down branch and a second pull-down branch connected between a control terminal of the switch transistor and ground. The first pull-down branch is configured to be activated or deactivated in response to a first enable signal, and when activated, generate a first pull-down current to discharge the control terminal of the switch transistor. The second pull-down branch is configured to be activated or deactivated in response to a second enable signal, and when activated, generate a second pull-down current to discharge the control terminal of the switch transistor. The first pull-down branch is configured to be activated earlier than the second pull-down branch, or be deactivated later than the second pull-down branch.

### CROSS-REFERENCE TO RELATED APPLICATIONS

This application claims priority to Chinese Patent Application No. 202411426128.4, filed on October 12, 2024, and entitled “Low-Side Switch Circuit, Control Method, Integrated Circuit and Electronic Device,” which is hereby incorporated by reference in its entirety.

### TECHNICAL FIELD

The present application relates to the field of electronic circuits, and more specifically, to a low-side switch circuit and its control method, a low-side switch integrated circuit, and an electronic device.

### BACKGROUND

As a key component of the Electronic Control Unit (ECU), low-side switch integrated circuits are widely used in automotive applications for controlling various loads, such as lights, heaters, and motors. A low-side switch integrated circuit typically comprises a switch transistor, which is used to establish or disconnect a connection between a negative terminal of a load and the ground, thereby achieving switching control of the load.

However, existing low-side switch integrated circuits still face a relatively high risk of damage. For example, due to the presence of parasitic capacitance between a control terminal of the switch transistor and a terminal connected to the negative terminal of the load, the switch transistor may inadvertently turn on, potentially causing damage to the electronic components in the low-side switch integrated circuits.

### SUMMARY

Embodiments of the present application provide a low-side switch circuit, its control method, a low-side switch integrated circuit, and an electronic device, which have benefits of reducing the risk of damage to low-side switch integrated circuits.

In a first aspect, embodiments of the present application provide a low-side switch circuit. The low-side switch circuit is connected between a load and ground, and the load is connected to an input voltage bus. The low-side switch circuit comprises:

A first switch transistor, where the non-controlling terminals of the first switch transistor are connected between an output terminal and the ground, and the output terminal is connected to one terminal of the load via the low-side switch circuit;

A first pull-down branch, connected between the control terminal of the first switch transistor and the ground, and configured to activate or deactivate in response to a first enable signal. When first pull-down branch activates, it generates a first pull-down current to discharge the control terminal of the first switch transistor; and

A second pull-down branch, connected between the control terminal of the first switch transistor and the ground, and configured to activate or deactivate in response to a second enable signal. When the second pull-down branch activates, it generates a second pull-down current to discharge the control terminal of the first switch transistor.

The first pull-down branch activates in response to the first enable signal earlier than the second pull-down branch activating in response to the second enable signal, or the first pull-down branch deactivates in response to the first enable signal later than the second pull-down branch deactivating in response to the second enable signal.

In one or more embodiments, the first enable signal is complementary to a system enable signal of the low-side switch circuit, and the second enable signal is a delayed version of the first enable signal, delayed by a first preset duration.

In one or more embodiments, the low-side switch circuit further comprises:

A clamping branch, connected between the output terminal and the control terminal of the first switch transistor, and configured to clamp the voltage between the output terminal and the control terminal of the first switch transistor to not exceed a first preset clamping voltage.

In one or more embodiments, the clamping branch comprises at least one first diode and/or at least one first Zener diode;

The anode of a first diode is connected to the output terminal, and the cathode of the first diode is connected to the control terminal of the first switch transistor.

The anode of a first Zener diode is connected to the control terminal of the first switch transistor, and the cathode of the first Zener diode is connected to the output terminal.

In one or more embodiments, the first pull-down branch comprises a first switch and a first current source.

The first switch and the first current source are connected in series between the control terminal of the first switch transistor and the ground, and the first switch is controlled by the first enable signal to turn on or off.

In one or more embodiments, the second pull-down branch comprises a second switch transistor.

The control terminal of the second switch transistor receives the second enable signal, and the non-controlling terminals of the second switch transistor are connected between the control terminal of the first switch transistor and the ground.

In one or more embodiments, the low-side switch circuit further comprises an overvoltage protection branch, which is connected between the output terminal and the ground and further connected to the second pull-down branch. The overvoltage protection branch is configured to generate a first indication signal based on the voltage at the output terminal and to generate the second enable signal.

The second pull-down branch is further configured to activate or deactivate in response to the second enable signal when the voltage at the output terminal is less than a first preset voltage threshold, and to remain deactivated in response to the first indication signal when the voltage at the output terminal is equal to or greater than the first preset voltage threshold.

In one or more embodiments, when the voltage at the output terminal is greater than the first preset voltage threshold, the first indication signal is at a low level, and when the voltage at the output terminal is less than or equal to the first preset voltage threshold, the first indication signal is at a high level.

In one or more embodiments, the low-side switch circuit further comprises an overcurrent protection branch, which is connected to the output terminal, the first pull-down branch, and the second pull-down branch. The overcurrent protection branch is configured to generate a first detection signal representing the current flowing through the first switch transistor when it conducts, and to generate the first enable signal based on the first detection signal. When the first switch transistor is in the on-state, the second enable signal is the same as the first enable signal.

The first pull-down branch is also configured to activate in response to the first enable signal when the first detection signal is greater than a first preset threshold.

The second pull-down branch is also configured to activate in response to the second enable signal when the first detection signal is greater than the first preset threshold.

In one or more embodiments, the overcurrent protection branch comprises a third switch transistor, a first resistor, and a first comparator.

The control terminal of the third switch transistor is connected to the control terminal of the first switch transistor. The non-controlling terminals of the third switch transistor are connected to the output terminal and the non-inverting input terminal of the first comparator, respectively. The first resistor is connected between the non-inverting input terminal of the first comparator and the ground. The inverting input terminal of the first comparator receives a second preset voltage threshold. The output terminal of the first comparator outputs the first enable signal.

In one or more embodiments, the first comparator is a hysteresis comparator. When the input voltage at the non-inverting terminal of the first comparator rises to exceed the second preset voltage threshold, the first enable signal transitions from low to high. When the input voltage at the non-inverting terminal of the first comparator falls below a third preset voltage threshold, the first enable signal transitions from high to low. The third preset voltage threshold is lower than the second preset voltage threshold.

In one or more embodiments, the low-side switch circuit further comprises an overvoltage protection branch, which is connected between the output terminal and the ground and connected to the second pull-down branch. The overvoltage projection branch is configured to generate a first indication signal based on the voltage at the output terminal and to generate the second enable signal. When the voltage at the output terminal is equal to or greater than a first preset voltage threshold, the second enable signal is the same as the first indication signal.

The second pull-down branch is also configured to deactivate in response to the first indication signal when the voltage at the output terminal is equal to or greater than the first preset voltage threshold.

In one or more embodiments, the overvoltage protection branch comprises a clamping unit, a switching unit, and an AND gate.

The clamping unit is connected between the output terminal and the switching unit. The switching unit is connected to the first input terminal of the AND gate to deliver the first indication signal to the first input terminal of the AND gate. The output terminal of the AND gate is connected to the second pull-down branch. The second input terminal of the AND gate receives the first enable signal or a delayed version of the first enable signal that is delayed by a first preset duration.

The clamping unit is configured to be turned off when the voltage at the output terminal is less than the first preset voltage threshold and to be turned on when the voltage at the output terminal is equal to or greater than the first preset voltage threshold.

The switching unit is configured to set the first indication signal to high when the clamping unit is turned off and to set the first indication signal to low when the clamping unit is turned on.

In one or more embodiments, the clamping unit comprises at least one second diode and/or at least one second Zener diode.

The anode of a second diode is connected to the output terminal, and the cathode of the second diode is connected to the switching unit.

The anode of a second Zener diode is connected to the switching unit, and the cathode of the second Zener diode is connected to the output terminal.

In one or more embodiments, the switching unit comprises a second resistor, a third resistor, a fourth resistor, and a fourth switch transistor.

The second resistor and the third resistor are connected in series between the clamping unit and the ground, and a common node of the second resistor and the third resistor is connected to the control terminal of the fourth switch transistor. The non-controlling terminals of the fourth switch transistor are connected between the first input terminal of the AND gate and the ground, and the fourth resistor is connected between a first power supply and the first input terminal of the AND gate.

In a second aspect, embodiments of the present application provide a control method for a low-side switch circuit. The low-side switch circuit comprises a first switch transistor, a first pull-down branch and a second pull-down branch. The non-controlling terminals of the first switch transistor are connected between an output terminal and ground. The output terminal is connected to an input voltage bus through a load, and both the first and second pull-down branches are connected between the control terminal of the first switch transistor and ground.

The control method comprises: activating the first pull-down branch to generate a first pull-down current to discharge the control terminal of the first switch transistor; and After a first preset time from the activation of the first pull-down branch, activating the second pull-down branch to generate a second pull-down current to discharge the control terminal of the first switch transistor.

In a third aspect, embodiments of this application provide a control method for a low-side switch circuit. The low-side switch circuit comprises a first switch transistor, a first pull-down branch, and a second pull-down branch. The non-controlling terminals of the first switch transistor are connected between an output terminal and ground, and the output terminal is connected to an input voltage bus through a load. Both the first and second pull-down branches are connected between the control terminal of the first switch transistor and ground.

The control method comprises: when the first switch transistor is in a conducting state, detecting a first current flowing through the first switch transistor and a voltage at the output terminal; when the first current exceeds a first preset current threshold, activating both the first pull-down branch and the second pull-down branch, and generating a first pull-down current and a second pull-down current to discharge the control terminal of the first switch transistor; and subsequently, when the voltage at the output terminal exceeds a second preset voltage threshold, deactivating the second pull-down branch.

In one or more embodiments, the control method further comprises: when the voltage at the output terminal is less than or equal to the second preset voltage threshold and the first current increases to exceed the first preset current threshold, activating both the first pull-down branch and the second pull-down branch; subsequently, when the voltage at the output terminal exceeds the second preset voltage threshold, activating the second pull-down branch; and when the first current decreases to less than a second preset current threshold, deactivating both the first and second pull-down branches, wherein the second preset current threshold is less than the first preset current threshold.

In a fourth aspect, embodiments of this application provide a low-side switch integrated circuit, including the low-side switch circuit as described above.

In a fifth aspect, embodiments of this application provide an electronic device, including a load and the low-side switch integrated circuit as described above.

The beneficial effects of aspects of this application are as follows: The low-side switch circuit in the embodiments of this application comprises the first switch transistor, the first pull-down branch, and the second pull-down branch. The non-controlling terminals of the first switch transistor are connected between the output terminal and the ground, where the output terminal is the terminal of the low-side switch circuit that is connected to the load. The first pull-down branch is connected between the control terminal of the first switch transistor and the ground and is configured to activate or deactivate in response to the first enable signal. When activated, the first pull-down branch generates a first pull-down current to discharge the control terminal of the first switch transistor. The second pull-down branch is connected between the control terminal of the first switch transistor and the ground and is configured to activate or deactivate in response to the second enable signal. When activated, the second pull-down branch generates a second pull-down current to discharge the control terminal of the first switch transistor. The first pull-down branch is configured to activate in response to the first enable signal earlier than the second pull-down branch activating in response to the second enable signal, which reduces the risk of inadvertent conduction of the first switch transistor, thereby reducing the risk of damage to electronic components of the first switch transistor. The first pull-down branch may also be configured to deactivate later than the second pull-down branch, when the total current provided by both the first and second pull-down branches is too high, which allows the second pull-down branch to stop earlier and reduces the total current discharging the control terminal of the first switch transistor. This minimizes the risk of damage to the low-side switch circuit due to overvoltage.

### BRIEF DESCRIPTION OF THE DRAWINGS

One or more embodiments are illustrated exemplarily by the accompanying drawings, and these exemplary illustrations are not intended to limit the embodiments. Elements in the drawings having the same reference numerals denote similar elements.

FIG. 1 is a block diagram of a low-side switch circuit provided by an embodiment of this application;

FIG. 2 is a block diagram of a low-side switch circuit provided by another embodiment of this application;

FIG. 3 is block diagram of a low-side switch circuit provided by yet another embodiment of this application;

FIG. 4 is a schematic diagram of a circuit structure corresponding to the block diagram shown in FIG. 3;

FIG. 5 is a schematic diagram of three circuit structures of a clamping branch provided by an embodiment of this application;

FIG. 6 is a waveform diagram of signals in the circuit structure shown in FIG. 4;

FIG. 7 is a block diagram of a low-side switch circuit provided by another embodiment of this application;

FIG. 8 is a block diagram of a low-side switch circuit provided by yet another embodiment of this application;

FIG. 9 is a schematic diagram of a circuit structure corresponding to the block diagram shown in FIG. 8;

FIG. 10 is a schematic diagram of three circuit structures of a clamping unit provided by an embodiment of this application;

FIG. 11 is a waveform diagram of signals in the low-side switch circuit shown in FIG. 9;

FIG. 12 is a block diagram of a low-side switch circuit provided by yet another embodiment of this application;

FIG. 13 is a schematic diagram of the circuit structure corresponding to the block diagram shown in FIG. 12;

FIG. 14 is another schematic diagram of a circuit structure corresponding to the block diagram shown in FIG. 12;

FIG. 15 is a waveform diagram of signals in the circuit structure shown in FIG. 14;

FIG. 16 is a block diagram of a low-side switch circuit provided by another embodiment of this application;

FIG. 17 is a schematic diagram of a circuit structure corresponding to the block diagram shown in FIG. 16;

FIG. 18 is a waveform diagram of signals in the circuit structure shown in FIG. 17;

FIG. 19 is a flowchart of a control method for a low-side switch circuit provided by an embodiment of this application; and

FIG. 20 is another flowchart of a control method for a low-side switch circuit provided by an embodiment of this application.

### DETAILED DESCRIPTION OF ILLUSTRATIVE EMBODIMENTS

In order to make the objectives, technical solutions, and advantages of embodiments of this application clearer, the following will provide a clear and detailed description of the technical solutions in the embodiments of this application in conjunction with the accompanying drawings. It is evident that the described embodiments are part of embodiments of this application and not all of them. It should be understood that the specific embodiments described herein are merely for the purpose of explaining this application and do not limit it.

It should be noted that when a component is stated to be "connected" to another component, it may be directly connected to another component, or there may be one or more intervening components in between.

Furthermore, the technical features involved in various embodiments of this application described below may be combined with each other as long as they do not constitute a conflict.

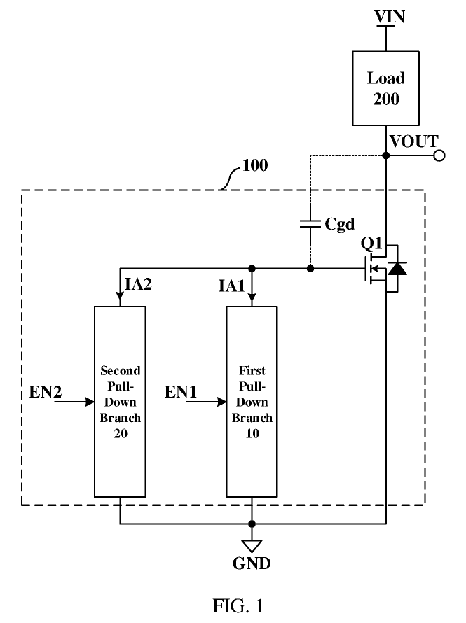

Referring to FIG. 1, FIG. 1 is a block diagram of a low-side switch circuit 100 according to embodiments of this application. As shown in FIG. 1, the low-side switch circuit 100 is connected between a load 200 and ground GND, and the load 200 is connected to an input voltage bus VIN. The low-side switch circuit 100 comprises a first switch transistor Q1, a first pull-down branch 10, and a second pull-down branch 20.

As used herein, a switch transistor includes a controlling terminal and two non-controlling terminals. The controlling terminal is a terminal of the switch transistor that is used to regulate the state (on/off) of the switch transistor, e.g., by modulating the flow of current in the switch transistor. The non-controlling terminals are two terminals of the switch transistor between which the primary current flows during operation of the switch transistor. As an example, the switch transistor is a MOSFET, the gate of the MOSFET is the controlling terminal of the switch transistor, and the source and the drain of the MOSFET are the non-controlling terminal of the switch transistor. Voltage is applied to the gate (i.e., the controlling terminal) of the MOSFET to control whether the channel between the source and drain conducts current.

The two non-controlling terminals of the first switch transistor Q1 are connected between the output terminal VOUT and the ground GND, where the output terminal VOUT connects the low-side switch circuit 100 to the load 200. In some embodiments, the first switch transistor Q1 is an NMOS transistor, with the control terminal of the first switch transistor Q1 being the gate of the NMOS transistor, a first terminal of the two non-controlling terminals of the first switch transistor Q1 being the source of the NMOS transistor, and a second terminal of the two non-controlling terminals of the first switch transistor Q1 being the drain of the NMOS transistor. The first pull-down branch 10 is connected between the control terminal of the first switch transistor Q1 and the ground GND. The second pull-down branch 20 is also connected between the control terminal of the first switch transistor Q1 and the ground GND.

In the following, embodiments of this application will be explained using the first switch transistor Q1 as an NMOS transistor as an example. In other embodiments, the first switch transistor Q1 may also be another controllable switch, such as a PMOS transistor, with the specific implementation process being similar to that of the NMOS transistor.

Specifically, the first pull-down branch 10 is configured to be activated or deactivated in response to a first enable signal EN1. The first pull-down branch 10 is also configured to output a first pull-down current IA1 to discharge the control terminal of the first switch transistor Q1 when the first pull-down branch 10 is activated. The second pull-down branch 20 is configured to be activated or deactivated in response to a second enable signal EN2. The second pull-down branch 20 is also configured to output a second pull-down current IA2 to discharge the control terminal of the first switch transistor Q1 when the second pull-down branch 20 is activated. By discharging the control terminal of the first switch transistor Q1, the first switch transistor Q1 can be turned off.

In some embodiments, the time at which the first pull-down branch 10 begins to activate in response to the first enable signal EN1 is earlier than the time at which the second pull-down branch 20 begins to activate in response to the second enable signal EN2. Thus, the control terminal of the first switch transistor Q1 is first discharged by the first pull-down current IA1, and then the control terminal of the first switch transistor Q1 is either further discharged or maintained in a pull-down state by the second pull-down current IA2.

By discharging the control terminal of the first switch transistor Q1, the first switch transistor Q1 can be turned off, and as the first switch transistor Q1 turns off, the voltage at the output terminal VOUT gradually increases. For the low-side switch circuit 100, the rate of voltage rise at the output terminal VOUT (i.e., the drain of the first switch transistor Q1) often needs to meet a specific requirement. For this reason, the current used to discharge the gate of the first switch transistor Q1 needs to remain stable and should not be excessive. But limited discharge current may lead to insufficient pull-down strength at the gate of the first switch transistor Q1, which can cause the first switch transistor Q1 to inadvertently turn on in some applications. For example, when the low-side switch circuit 100 is used as the low-side transistor in a bridge driving circuit, the voltage at the output terminal VOUT may experience a significant voltage step (dv/dt). For instance, when the load 200 is a switch transistor configured to conduct, the voltage at the output terminal VOUT may undergo a large voltage step. The step signal applied to the drain of the first switch transistor Q1 may be coupled to the gate of the first switch transistor Q1 through the parasitic capacitance Cgd between the drain and the gate of the first switch transistor Q1, causing the gate voltage of the first switch transistor Q1 to rise. Since the low-side switch circuit 100 is configured to discharge the control terminal of the first switch transistor Q1 through the first pull-down current IA1, if the first pull-down current IA1 is less than the pull-up current induced by the step signal across the parasitic capacitance Cgd, the first switch transistor Q1 will be turned on inadvertently. At this time, since the load 200 is a switch transistor and has been configured to conduct, this will cause a short circuit between the input voltage bus VIN and the ground, potentially damaging the load 200 or components within the low-side switch circuit 100. In view of this, embodiments of the present application further configure the second pull-down current IA2 to discharge the control terminal of the first switch transistor Q1, so that after the first pull-down current IA1 discharges the control terminal of the first switch transistor Q1 in order to turn it off, the increased pull-down capacity provided by the second pull-down current IA2 can prevent the first switch transistor Q1 from turning back on due to transient changes in its drain voltage, thereby helping prevent inadvertent turn on of the first switch transistor Q1 and reduce the risk of damage to the components within the low-side switch circuit 100.

In some other embodiments, the first pull-down branch 10 may deactivate later than the second pull-down branch 20, which deactivates in response to the second enable signal EN2. In this case, when both the first pull-down branch 10 and the second pull-down branch 20 are activated, the second pull-down branch 20 is deactivated first to halt the output of the second pull-down current IA2. Later, the first pull-down branch 10 is controlled to deactivate to halt the output of the first pull-down current IA1. Therefore, when the total current provided by the first pull-down branch IA1 and the second pull-down branch IA2 is too large, deactivating the second pull-down branch IA2 earlier to reduce the total current can lower the risk of damage to the low-side switch 100. It can be understood that in this embodiment, the time when the first pull-down branch 10 is deactivated in response to the first enable signal EN1 is later than the time when the second pull-down branch 20 is deactivated in response to the second enable signal EN2.

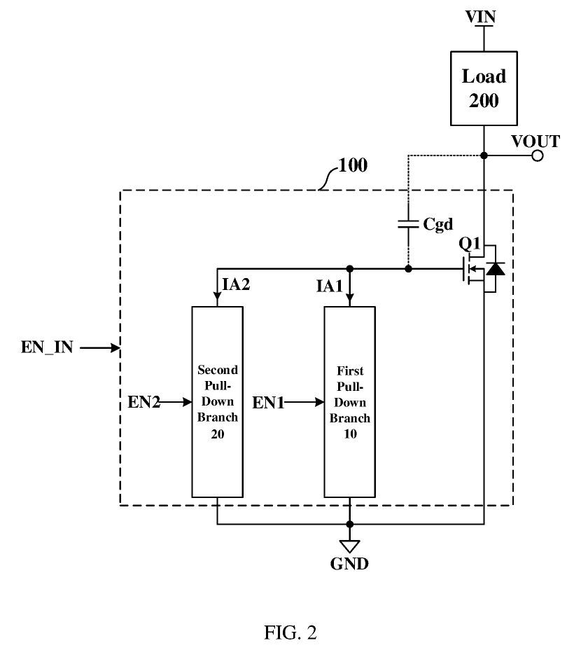

In some embodiments, as shown in FIG. 2, the first enable signal EN1 and a system enable signal EN_IN of the low-side switch circuit 100 are complementary signals, and the second enable signal EN2 is a delayed version of the first enable signal EN1, e.g., delayed by a first preset duration. That is, the time interval between the moment the first pull-down branch 10 activates in response to the first enable signal EN1 and the moment the second pull-down branch 20 activates in response to the second enable signal EN2 is the first preset duration. The first preset duration may be set based on actual application scenarios, and this application does not impose specific limitations on this.

The system enable signal EN_IN of the low-side switch circuit 100 is used to control the enablement of an integrated circuit that comprises the low-side switch circuit 100, for example, in some implementations, the integrated circuit including the low-side switch circuit 100 is equipped with peripheral circuits such as an internal power supply circuit and an oscillator circuit, and the system enable signal EN_IN is used to control the enablement of these peripheral circuits. In some implementations, the system enable signal EN_IN may also be used to control the enablement of the first switch transistor Q1, that is, to control the turning on or off of the first switch transistor Q1; for instance, in some implementations, when the system enable signal EN_IN is at a high level, the first switch transistor Q1 is turned on.

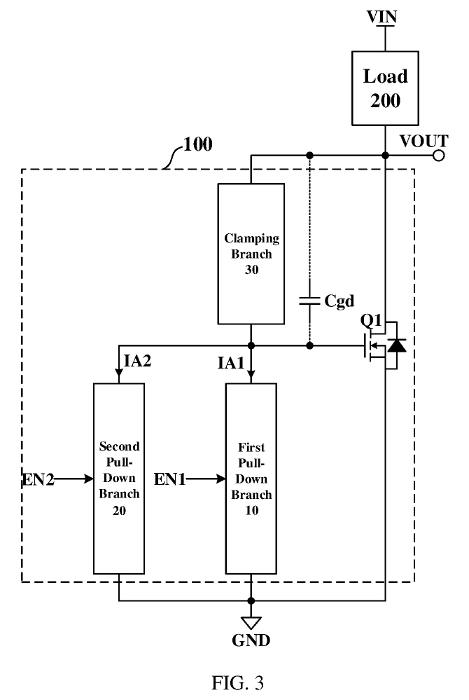

In some implementations, as shown in FIG. 3, the low-side switch circuit 100 may further comprise a clamping branch 30. The clamping branch 30 is connected between the output terminal VOUT and the control terminal of the first switch transistor Q1.

Specifically, the clamping branch 30 is configured to clamp the voltage between the output terminal VOUT and the control terminal of the first switch transistor Q1 to not exceed a first preset clamping voltage. That is, limited by the clamping branch 30, the voltage between the output terminal VOUT and the control terminal of the first switch transistor Q1 is less than or equal to the first preset clamping voltage. When the voltage between the output terminal VOUT and the control terminal of the first switch transistor Q1 increases to be greater than the first preset clamping voltage, the clamping branch 30 conducts and clamps the voltage between the output terminal VOUT and the control terminal of the first switch transistor Q1 to the first preset clamping voltage. The first preset clamping voltage may be determined by the characteristics of the clamping branch 30 and be set based on actual application scenarios.

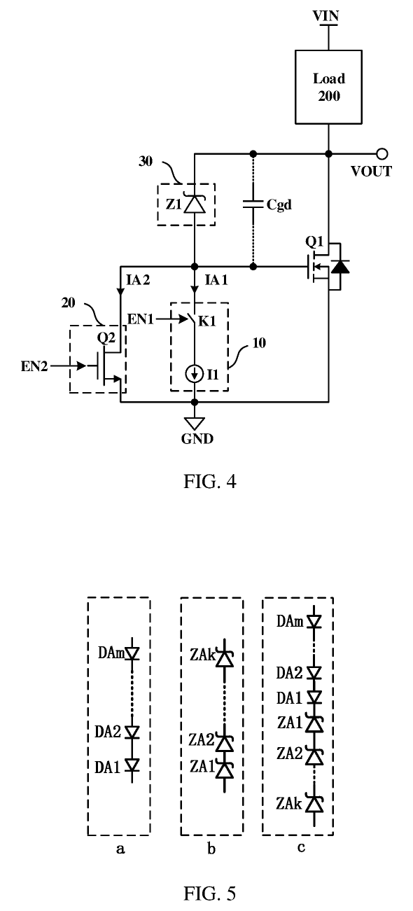

Please refer to FIG. 4, which is a schematic diagram of a circuit structure corresponding to that shown in FIG. 3. As shown in FIG. 4, the clamping branch 30 comprises a Zener diode Z1. The anode of the Zener diode Z1 is connected to the control terminal of the first switch transistor Q1, and the cathode of the Zener diode Z1 is connected to the output terminal VOUT.

In this embodiment, the first pull-down branch 10 comprises a first switch K1 and a first current source I1.

The first switch K1 is connected in series with the first current source I1 between the control terminal of the first switch transistor Q1 and the ground GND. The first switch K1 is controlled to turn on or off by the first enable signal EN1. The current provided by the first current source I1 is the first pull-down current IA1.

In this embodiment, the second pull-down branch 20 comprises a second switch transistor Q2.

The control terminal of the second switch transistor Q2 receives the second enable signal EN2, and the non-controlling terminals of the second switch transistor Q2 are connected between the output terminal VOUT and the ground GND.

Embodiments of the present application are described using the second switch transistor Q2 as an NMOS transistor as an example, where the control terminal of the second switch transistor Q2 is the gate of the NMOS transistor, a first terminal of the non-controlling terminals of the second switch transistor Q2 is the source of the NMOS transistor, and a second terminal of the non-controlling terminals of the second switch transistor Q2 is the drain of the NMOS transistor. In other embodiments, the second switch transistor Q2 may also be another type of switch, such as a PMOS transistor, with the implementation process being similar to that of the NMOS transistor.

In FIG. 4, when the low-side switch circuit 100 needs to control the first switch transistor Q1 to turn off, the first enable signal EN1 changes from low level to high level, and the first switch K1 is controlled to turn on. As a result, the first pull-down current IA1 discharges the gate of the first switch transistor Q1, thereby turning off the first switch transistor Q1. Following the transition of the first enable signal EN1 from low to high level, the second enable signal EN2 transitions from low to high level after a first preset time interval, turning on the second switch transistor Q2 to provide the second pull-down current IA2. The introduction of the second pull-down current increases the total pull-down capability, which prevents the first switch transistor Q1 from inadvertently turning on due to transient changes in its drain voltage, after the first switch transistor Q1 has turned off. In summary, by selectively activating the second pull-down branch 20 in addition to activating first pull-down branch 10, the low-side switch circuit 100 can be better protected when voltage transients appear at the output terminal VOUT. The Zener diode Z1 is used to clamp the voltage difference between the drain and gate of the first switch transistor Q1. When the voltage difference between the drain and gate of the first switch transistor Q1 increases to the breakdown voltage of the Zener diode Z1, the voltage difference between the drain and gate of the first switch transistor Q1 is clamped to the first preset clamping voltage.

Please refer to FIG. 5, which provides three additional implementations of the clamping branch 30 according to the embodiments of this application. Specifically, as shown in diagram a of FIG. 5, the clamping branch 30 in this example comprises at least a first group of diodes. The first group of diodes comprises a first diode DA1, a second diode DA2, ..., and an m-th diode DAm, where m is an integer greater than or equal to 1. The anodes of the first diode DA1, the second diode DA2, ..., and the m-th diode DAm are directly or indirectly connected to the output terminal VOUT. The cathodes of the first diode DA1, the second diode DA2, ..., and the m-th diode DAm are directly or indirectly connected to the control terminal of the first switch transistor Q1. As an example, DA1, DA2, …, DAm are connected in series, the anode of DAm is connected to the output terminal VOUT, and the cathode of DA1 is connected to the control terminal of the first switch transistor Q1.

As shown in diagram b of FIG. 5, the clamping branch 30 in this example comprises at least a first group of Zener diodes. The first group of Zener diodes comprises a first Zener diode ZA1, a second Zener diode ZA2, ..., and a k-th Zener diode ZAk, where k is an integer greater than or equal to 1. The anodes of the first Zener diode ZA1, the second Zener diode ZA2, ..., and the k-th Zener diode ZAk are directly or indirectly connected to the control terminal of the first switch transistor Q1. The cathodes of the first Zener diode ZA1, the second Zener diode ZA2, ..., and the k-th Zener diode ZAk are directly or indirectly connected to the output terminal VOUT. As an example, ZA1, ZA2, …, ZAk are connected in series, the cathode of ZAk is connected to the output terminal VOUT, and the anode of ZA1 is connected to the control terminal of the first switch transistor Q1.

As shown in diagram c of FIG. 5, the clamping branch 30 in this example comprises at least one diode of the first group of diodes and at least one Zener diode of the first group of Zener diodes. As an example, the clamping branch 30 comprises the diodes as shown in diagram a and the Zener diodes as shown in diagram b of FIG. 5. Specifically, the first group of diodes DA1-DAm and the first group of Zener diodes are connected in series, the cathode of DA1 is connected to the cathode of ZA1, the anode of DAm is connected to the output terminal VOUT, and the anode of ZAk is connected to the control terminal of the first switch transistor Q1. The specific implementation process can refer to the descriptions of diagram a and diagram b of FIG. 5, which are not repeated here.

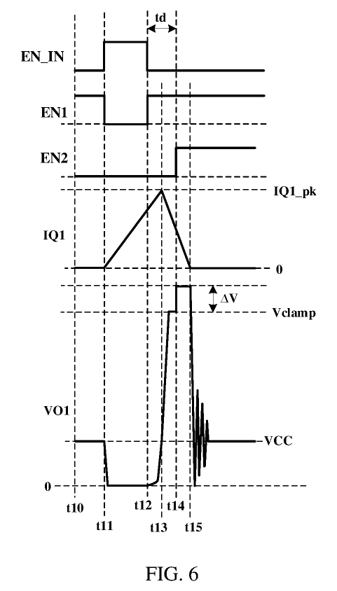

Please refer to FIG. 6, which exemplarily illustrates the waveforms of the signals in the circuit structure shown in FIG. 4. In FIG. 6, the horizontal axis represents time, and FIG. 6 shows, along the vertical axis from top to bottom, waveforms of the system enable signal EN_IN of the low-side switch circuit 100, the first enable signal EN1, the second enable signal EN2, the current IQ1 flowing through the first switch transistor Q1, and the voltage VO1 at the output terminal VOUT. The dashed lines parallel to the horizontal axis from top to bottom represent a peak value IQ1_pk of the current IQ1, a baseline of the current IQ1 at 0A, the clamping voltage Vclamp, and a voltage of the input voltage bus VCC. In this embodiment, the load 200 is set as an inductive load, and the first enable signal EN1 and the system enable signal EN_IN of the low-side switch circuit 100 are complementary signals.

As shown in FIG. 6, at time t10, the first switch transistor Q1 is in the off state, and the voltage VO1 of the output terminal VOUT is the voltage of an input voltage bus VCC of the low-side switch circuit 100. At time t11, the system enable signal EN_IN changes to high level, which controls the first switch transistor Q1 to turn on. Correspondingly, the first enable signal EN1 changes to low level, and the first switch K1 turns off. The voltage VO1 of the output terminal VOUT drops rapidly, while the current IQ1 flowing through the first switch transistor Q1 increases linearly. The slope of the increase in the current IQ1 is VCC/Lout, where Lout is the inductance value of the inductive load.

At time t12, the system enable signal EN_IN changes to low level, and the first enable signal EN1 changes to high level, controlling the first switch transistor Q1 to start turning off, and the first pull-down branch 10 outputs a first pull-down current IA1 to discharge the gate of the first switch transistor Q1. By time t13, the first switch transistor Q1 completes turning off, and the current IQ1 reaches its peak IQ1_pk. As the first switch transistor Q1 completes turning off, the current stored in the inductive load begins to raise the voltage VO1 at the output terminal VOUT to the clamping voltage Vclamp of the Zener diode Z1. At this point, the Zener diode Z1 undergoes reverse breakdown, and the first pull-down branch 10 discharges the inductive load through the clamping branch 30, causing the current IQ1 to begin decreasing.

At time t14, after a delay of the first preset time duration td, and with the arrival of the rising edge of the second enable signal EN2, the second pull-down branch 20 is activated, i.e., the second switch transistor Q2 is turned on. Consequently, the second pull-down current IA2 flowing through the second pull-down branch 20 is combined with the first pull-down current IA1 flowing through the first pull-down branch 10, significantly increasing the current flowing through the Zener diode Z1. Since the clamping voltage of the Zener diode Z1 increases with the increasing current flowing through it, the voltage VO1 at the output terminal VOUT will also rise quickly to be ∆V higher than the clamping voltage Vclamp, due to activation of the second pull-down branch 20. This makes the first switch transistor Q1 be exposed to a voltage higher than the clamping voltage Vclamp of the Zener diode Z1, resulting in an overvoltage risk. At time t15, as the inductive load completes discharging, the current IQ1 drops to zero, and the voltage VO1 at the output terminal VOUT falls rapidly and stabilizes after a few oscillations, returning to the voltage of the input voltage bus VCC.

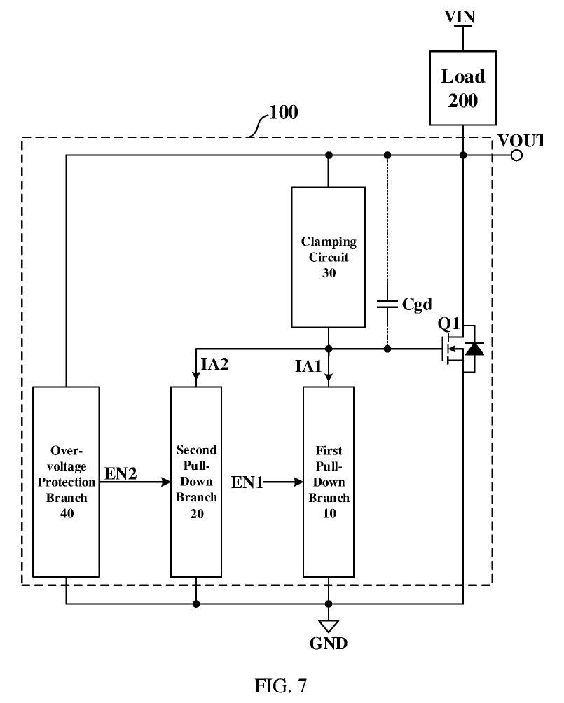

As shown in the example of FIG. 6, the circuit structure shown in FIG. 4 may cause the first switch transistor Q1 to be damaged due to overvoltage. To address this, embodiments of this application introduce an overvoltage protection branch to reduce the risk of the first switch transistor Q1 being damaged due to overvoltage. Specifically, in some embodiments, as shown in FIG. 7, the low-side switch circuit 100 may further comprise an overvoltage protection branch 40. The overvoltage protection branch 40 is connected between the output terminal VOUT and ground GND and is connected to the second pull-down branch 20.

Specifically, the overvoltage protection branch 40 is configured to generate a first indication signal S1 based on the voltage at the output terminal VOUT and output the second enable signal EN2 to the second pull-down branch 20. The second pull-down branch 20 is further configured to activate or deactivate in response to the second enable signal EN2 when the voltage at the output terminal VOUT is less than a first preset voltage threshold, and is configured to remain deactivated in response to the first indication signal S1 when the voltage at the output terminal VOUT is greater than or equal to the first preset voltage threshold (at which time, the second enable signal EN2 and the first indication signal S1 are the same signal). In this embodiment, by configuring the overvoltage protection circuit 40 to detect the voltage at the output terminal VOUT in real-time, the drain-source voltage difference (the voltage difference between the drain and source) of the first switch transistor Q1 is detected in real-time, based on which, the second pull-down branch 20 may be allowed to be activated only when the drain-source voltage difference of the first switch transistor Q1 is less than the first preset voltage threshold. This mitigates the risk of overvoltage on the first switch transistor Q1 caused by activating the second pull-down branch 20 during the period when the drain-source voltage difference reaches the clamping voltage Vclamp. The first preset voltage threshold may be set based on actual application scenarios, and this application does not impose specific limitations on it. The first preset voltage threshold needs to be less than or equal to the clamping voltage Vclamp.

In some embodiments, when the voltage at the output terminal VOUT is greater than the first preset voltage threshold, the first indication signal S1 is at a low-level, and when the voltage at the output terminal VOUT is not greater than the first preset voltage threshold, the first indication signal S1 is at a high-level.

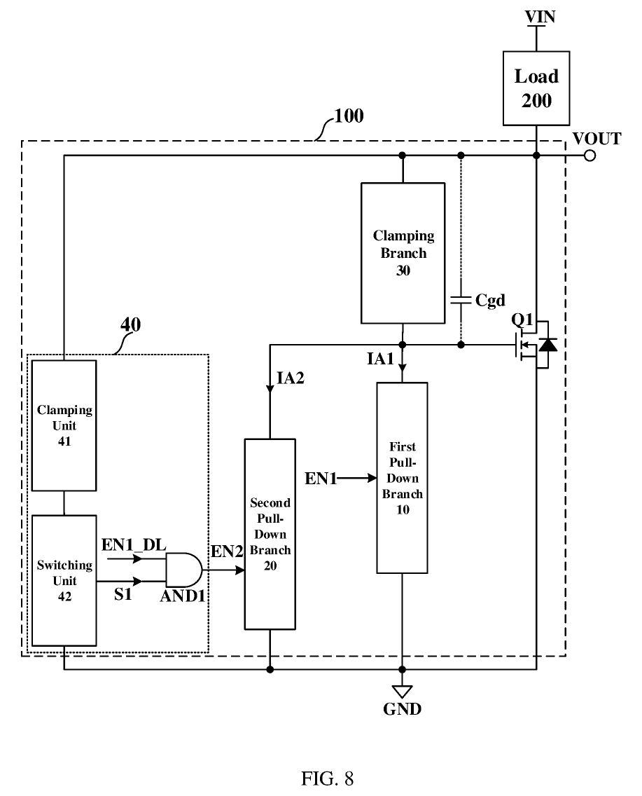

In some embodiments, as shown in FIG. 8, the overvoltage protection branch 40 comprises a clamping unit 41, a switching unit 42, and an AND gate AND1.The clamping unit 41 is connected between the output terminal VOUT and the switching unit 42, and the switching unit 42 is connected to a first input terminal of the AND gate AND1, to output the first indication signal S1 to the first input terminal of the AND gate AND1. The output terminal of the AND gate AND1 is connected to the second pull-down branch 20. A second input terminal of the AND gate AND1 receives a signal EN1_DL, which is a delayed version of the first enable signal EN1 delayed by a first preset duration.

Specifically, the clamping unit 41 is configured to turn off when the voltage at the output terminal VOUT is less than the first preset voltage threshold, and to turn on when the voltage at the output terminal VOUT is greater than or equal to the first preset voltage threshold. The switching unit 42 is configured to set the first indication signal S1 to a high level when the clamping unit 41 is turned off, so that the second enable signal EN2 is same as the signal EN1_DL, the delayed version of the first enable signal EN1 delayed by the first preset duration. The second pull-down branch 20 is activated or deactivated in response to the second enable signal (i.e., the signal EN1_DL). The switching unit 42 is further configured to set the first indication signal S1 to a low level when the clamping unit 41 is turned on, and the second enable signal EN2 is accordingly kept at a low level, so that the second pull-down branch 20 remains deactivated in response to the first indication signal S1.

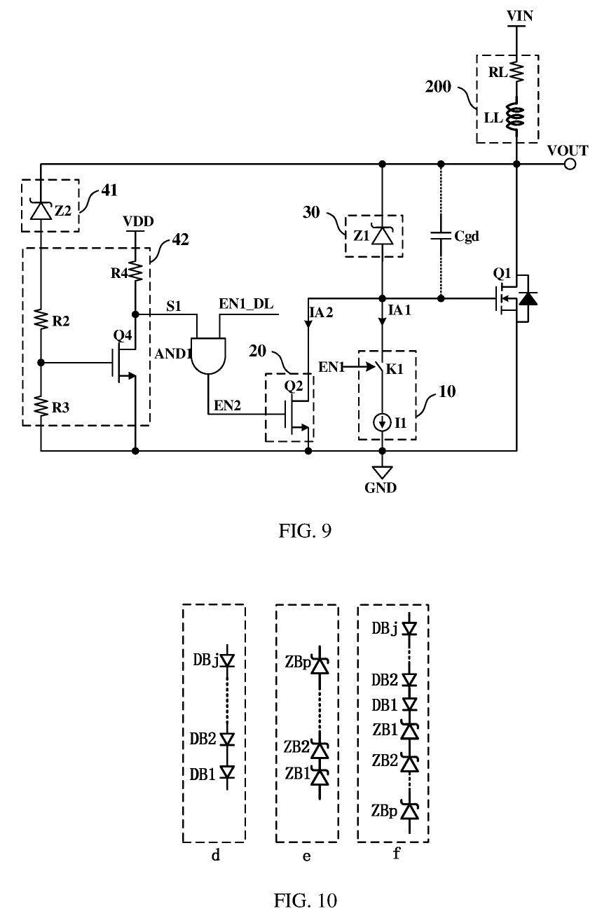

Referring to FIG. 9, FIG. 9 illustrates an example circuit structure corresponding to the structure shown in FIG. 8. The first pull-down branch 10, the second pull-down branch 20, and the clamping branch 30 are the same as those described with respect to FIG. 4 and will not be further described here. This embodiment also illustratively shows the circuit structure when the load 200 is an inductive load, e.g., as shown, the load 200 comprises an inductor LL and a resistor RL connected in series between the input voltage bus VIN and the output terminal VOUT.

As shown in FIG. 9, the clamping unit 41 comprises a Zener diode Z2. The anode of the Zener diode Z2 is connected to the switching unit 42, and the cathode of the Zener diode Z2 is connected to the output terminal VOUT.

In this embodiment, the switching unit 42 comprises a second resistor R2, a third resistor R3, a fourth resistor R4, and a fourth switch transistor Q4. The second resistor R2 and the third resistor R3 are connected in series between the clamping unit 41 and the ground GND, and the connection point (common node) between the second resistor R2 and the third resistor R3 is connected to the control terminal of the fourth switch transistor Q4. The non-controlling terminals of the fourth switch transistor Q4 are connected between the first input terminal of the AND gate AND1 and the ground GND, and the fourth resistor R4 is connected between a first power supply VDD and the first input terminal of the AND gate AND1. The first power supply VDD is the internal power supply of the low-side switch integrated circuit.

In various embodiments of this application, the fourth switch transistor Q4 is exemplarily described as an NMOS transistor as an example. The control terminal of the fourth switch transistor Q4 is the gate of the NMOS transistor, a first non-controlling terminal of the fourth switch transistor Q4 is the source of the NMOS transistor, and a second non-controlling terminal is the drain of the NMOS transistor. In other embodiments, the fourth switch transistor Q4 may also be another controllable switch, such as a PMOS transistor, and the specific implementation process is similar to that of the NMOS transistor.

In FIG. 9, the Zener diode Z2 may be used to detect the drain-source voltage difference of the first switch transistor Q1, and the Zener diode Z2 conducts when the drain-source voltage difference of the first switch transistor Q1 exceeds the first preset voltage threshold. Then, the current flowing through the Zener diode Z2 generates a voltage across the third resistor R3, turning on the fourth switch transistor Q4, which pulls the first indication signal S1 low. Consequently, activating the second pull-down branch 20 is prohibited, i.e., the second pull-down branch 20 remains inactive (corresponding to the second switch Q2 remaining off), thereby providing overvoltage protection for the first switch transistor Q1. When the drain-source voltage difference of the first switch transistor Q1 is less than or equal to the first preset voltage threshold, the Zener diode Z2 turns off, the fourth switch transistor Q4 turns off, and the first indication signal S1 remains high, allowing the second switch Q2 to be turned on or off (i.e. the second pull-down branch 20 to be activated or deactivated) in response to the signal EN1_DL, which is the delayed version of the first enable signal EN1.

Referring to FIG. 10, FIG. 10 provides three alternative example implementations of the clamping unit 41 according to embodiments of this application. Specifically, as shown in diagram d of FIG. 10, the clamping unit 41 comprises at least one second group of diodes, which includes a first diode DB1, a second diode DB2, ..., and a j-th diode DBj, where j is an integer greater than or equal to 1. The anodes of the first diode DB1, the second diode DB2, ..., and the j-th diode DBj are connected, either directly or indirectly, to the output terminal VOUT, and the cathodes of the first diode DB1, the second diode DB2, ..., and the j-th diode DBj are connected, either directly or indirectly, to the switching unit 42.

As shown in diagram e of FIG. 10, the clamping unit 41 comprises at least one second group of Zener diodes, which includes a first Zener diode ZB1, a second Zener diode ZB2, ..., and a p-th Zener diode ZBp, where p is an integer greater than or equal to 1. The anode of the first Zener diode ZB1, the second Zener diode ZB2, ..., and the p-th Zener diode ZBp are connected, either directly or indirectly, to the switching unit 42, and the cathode of the first Zener diode ZB1, the second Zener diode ZB2, ..., and the p-th Zener diode ZBp are connected, either directly or indirectly, to the output terminal VOUT.

As shown in diagram f of FIG. 10, the clamp unit 41 comprises at least one diode of the second group of diodes and at least one Zener diode of the second group of Zener diodes. As an example, the clamp unit 41 comprises the diodes of diagram d and the Zener diodes of diagram e in FIG. 10. The specific implementation process can refer to the description for diagrams d and e in FIG. 10 and will not be repeated here.

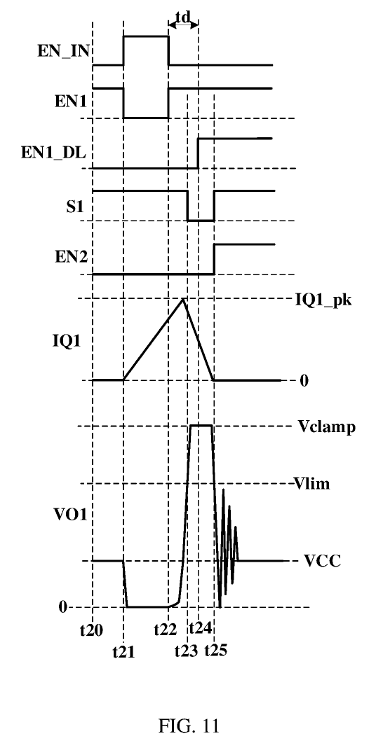

Please refer to FIG. 11, which exemplarily shows waveforms of the signals in the circuit structure shown in FIG. 9. In FIG. 11, the horizontal axis represents time. FIG. 11 shows, along the vertical axis from top to bottom, waveforms of the system enable signal EN_IN of the low-side switch circuit 100, the first enable signal EN1, the signal EN1_DL, the first indication signal S1, the second enable signal EN2, the current IQ1 flowing through the first switch transistor Q1, and the voltage VO1 at the output terminal VOUT, where the signal EN1_DL is a delayed version of the first enable signal EN1, delayed by a first preset duration td. FIG. 11 also shown, in dashed lines parallel to the horizontal axis, the peak value IQ1_pk of the current IQ1, the reference where the current IQ1 equals 0A, the clamp voltage Vclamp, the first preset voltage threshold Vlim, and the voltage of the input voltage bus VCC. In this embodiment, the load 200 is an inductive load, and the first enable signal EN1 and the system enable signal EN_IN of the low-side switch circuit 100 are complementary signals.

As shown in FIG. 11, before time t23, the first indication signal S1 remains high, and the second enable signal EN2 at the output of AND1 is the same as the signal EN1_DL, which is a delayed version of the first enable signal EN1 delayed by the first preset duration td. At time t23, the voltage VO1 at the output terminal VOUT rises to the first preset voltage threshold Vlim, at which point the Zener diode Z2 conducts due to reverse breakdown, driving the fourth switch transistor Q4 to conduct. This consequently causes the first indication signal S1 to transition to the low level, thereby disabling the second pull-down branch 20 to keep it in a deactivated state. In this embodiment, since the overvoltage protection branch 40 has been added, at time t24, when the signal EN1_DL becomes high, and because the voltage VO1 at the output terminal VOUT is still higher than the first preset voltage threshold Vlim, the first indication signal S1 remains low. The control signal of the second pull-down branch 20 (i.e., the second enable signal EN2) stays low, and the second pull-down branch 20 will not be activated, thus preventing the situation where the voltage VO1 at the output terminal VOUT exceeds the clamp voltage Vclamp, as seen in FIG. 6. The second pull-down branch 20 remains deactivated until time t25, when the voltage VO1 at the output terminal VOUT drops below the first preset voltage threshold Vlim, causing the Zener diode Z2 to turn off (recover from reverse break down), the fourth switch transistor Q4 to turn off, and the first indication signal S1 to transition to high. The second enable signal EN2 at the output of AND1 also transitions to high, activating the second pull-down branch 20. At this point, even if there is a sudden change in the voltage VO1 at the output terminal VOUT, it cannot inadvertently turn on the first switch transistor Q1.

It can be understood that in the embodiments of this application, by providing the first pull-down branch 10 and the second pull-down branch 20, the rate of turning off the first switch transistor Q1 can be increased in certain fault conditions, improving the reliability of the low-side switch circuit 100. For example, in the case of a short circuit in the load 200, the first switch transistor Q1 can be turned off more quickly by enabling both the first pull-down branch 10 and the second pull-down branch 20 simultaneously.

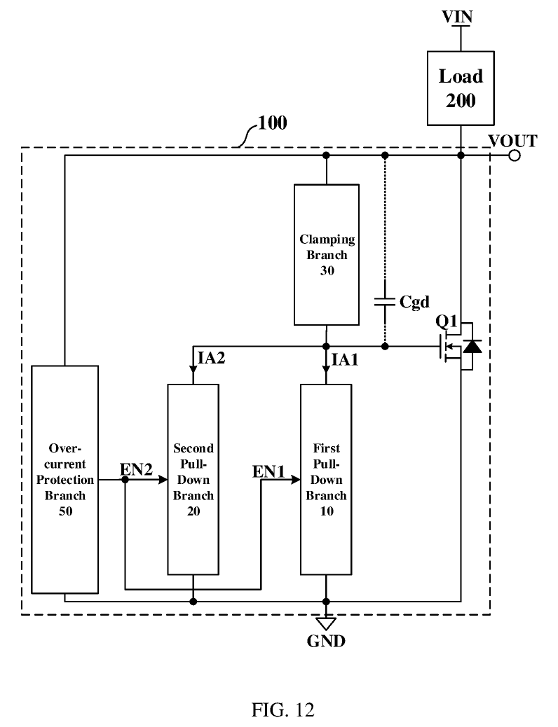

In some embodiments, as shown in FIG. 12, the low-side switch circuit 100 may also comprise an overcurrent protection branch 50. This embodiment takes the structure shown in FIG. 3 and adds the overcurrent protection circuit 50 as an example. The overcurrent protection branch 50 is connected to the output terminal VOUT, the first pull-down branch 10, and the second pull-down branch 20.

Specifically, the overcurrent protection branch 50 is configured to generate a first detection signal (denoted as VSNS) representing the current flowing through the first switch transistor Q1 when the first switch transistor Q1 is on, and based on the first detection signal VSNS, output the first enable signal EN1. When the first switch transistor Q1 is in the on-state, the second enable signal EN2 and the first enable signal EN1 are the same signal. The first pull-down branch 10 is also configured to activate in response to the first enable signal EN1 when the first detection signal VSNS is greater than a first preset threshold. The second pull-down branch 20 is also configured to activate in response to the second enable signal EN2 when the first detection signal VSNS is greater than the first preset threshold. The first detection signal VSNS being greater than the first preset threshold corresponds to the current flowing through the first switch transistor Q1 being greater than a first preset current threshold. In this embodiment, by enabling (activating) both the first pull-down branch 10 and the second pull-down branch 20 simultaneously, the first switch transistor Q1 can be turned off more quickly, providing protection for the first switch transistor Q1 in the event of overcurrent (i.e., the current flowing through the first switch transistor Q1 exceeds the first preset current threshold).

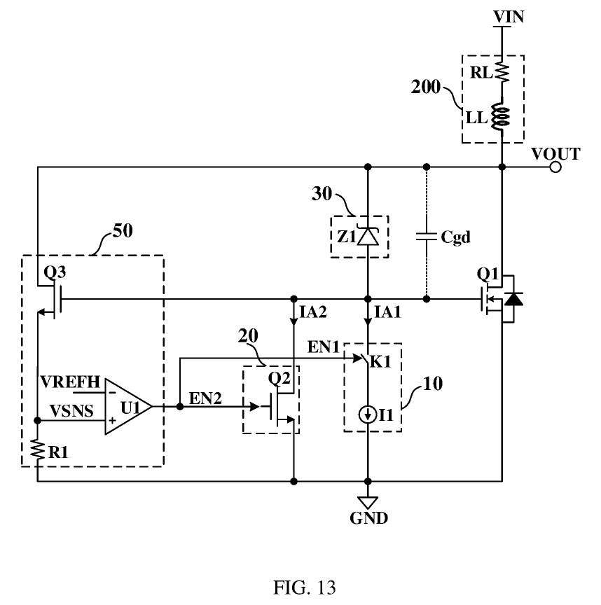

Please refer to FIG. 13, which shows a circuit structure corresponding to the structure shown in FIG. 12. The first pull-down branch 10, the second pull-down branch 20, and the clamp branch 30 are the same as those described in the previous embodiments and will not be repeated here. This embodiment also exemplarily shows the circuit structure where the load 200 is an inductive load. As shown, the load 200 comprises an inductor LL and a resistor RL connected in series between the input voltage bus VIN and the output terminal VOUT.

As shown in FIG. 13, the overcurrent protection branch 50 comprises a third switch transistor Q3, a first resistor R1, and a first comparator U1.

Specifically, the control terminal of the third switch transistor Q3 is connected to the control terminal of the first switch transistor Q1. The non-controlling terminals of the third switch transistor Q3 are connected to the output terminal VOUT and the non-inverting input terminal of the first comparator U1. The first resistor R1 is connected between the non-inverting input terminal of the first comparator U1 and the ground GND. The inverting input terminal of the first comparator U1 receives a second preset voltage threshold VREFH. The output terminal of the first comparator U1 outputs the first enable signal EN1.

In the various embodiments of this application, the third switch transistor Q3 is described as an NMOS transistor as an example, where the control terminal of the third switch transistor Q3 is the gate of the NMOS transistor, a first terminal of the non-controlling terminals is the source of the NMOS transistor, and a second terminal of the non-controlling terminals is the drain of the NMOS transistor. In other embodiments, the third switch transistor Q3 may be other controllable switches, such as a PMOS transistor, and the specific implementation process is similar to that of the NMOS transistor.

In FIG. 13, the third switch transistor Q3 and the first switch transistor Q1 form a common-gate and common-drain structure. In an example, the width-to-length ratio of the first switch transistor Q1 may be M times that of the third switch transistor Q3, where M is much greater than 1. The third switch transistor Q3 mirrors the current IQ1 flowing through the first switch transistor Q1, and generates a voltage across the first resistor R1, where the voltage represents the current IQ1 flowing through the first switch transistor Q1 and is input into the non-inverting input terminal of the first comparator U1. The voltage is the first detection signal VSNS. The inverting input terminal of the first comparator U1 is connected to the second preset voltage threshold VREFH representing the overcurrent protection threshold voltage. Note that in this embodiment, the first detection signal VSNS is a voltage signal as an example. In other embodiments, the first detection signal may be current.

When the first switch transistor Q1 is conducting, and if a short circuit occurs at the load 200, causing the input voltage bus VIN to short with the output terminal VOUT, the current IQ1 flowing through the first switch transistor Q1 increases rapidly, and the current flowing through the third switch transistor Q3 also increases rapidly along with IQ1, until the voltage drop VSNS across the first resistor R1 exceeds the second preset voltage threshold VREFH. The output of the first comparator U1 (i.e., the first enable signal EN1 and the second enable signal EN2) switches to a high level, driving the first pull-down branch 10 and the second pull-down branch 20 together to turn off the first switch transistor Q1, thereby achieving overcurrent protection in the low-side switch circuit 100.

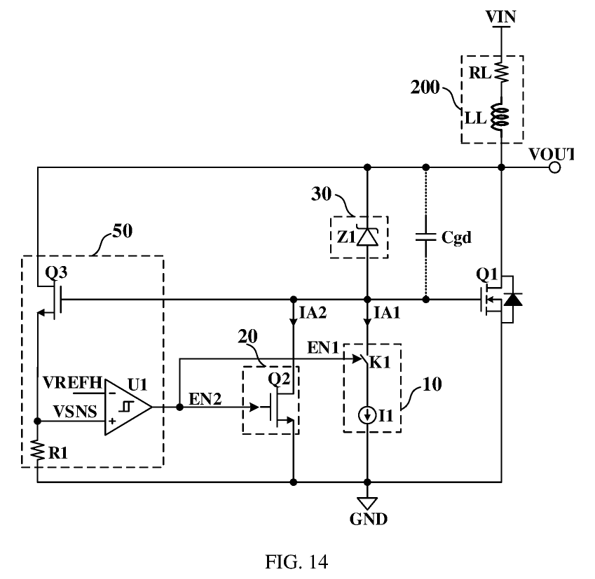

In some embodiments, as shown in FIG. 14, the first comparator U1 may be a hysteresis comparator. When the input voltage at the non-inverting input terminal of the first comparator U1 rises above the second preset voltage threshold VREFH, the first enable signal EN1 flips from low to high. When the input voltage at the non-inverting input terminal of the first comparator U1 drops below a third preset voltage threshold VREFL, the first enable signal EN1 flips from high to low, where the third preset voltage threshold VREFL is lower than the second preset voltage threshold VREFH.

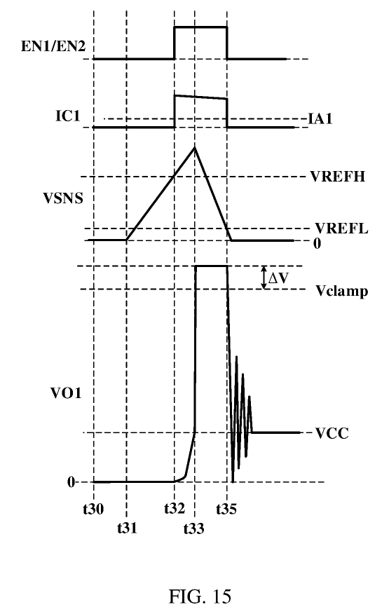

Referring to FIG. 15, FIG.15 exemplarily shows waveforms of the signals in the circuit structure shown in FIG. 14. In FIG. 15, the horizontal axis represents time, and FIG. 15 shows, along the vertical axis from top to bottom, waveforms of the first enable signal EN1/second enable signal EN2, the sum of the first pull-down current IA1 and the second pull-down current IA2, i.e., current IC1, the voltage at the non-inverting input terminal of the first comparator U1(i.e., the first detection signal VSNS), and the voltage VO1 at the output terminal VOUT. FIG. 15 also shows, in dashed lines parallel to the horizontal axis from top to bottom, the first pull-down current IA1, the second preset voltage threshold VREFH, the third preset voltage threshold VREFL, the reference for the first detection signal VSNS being 0V, the clamp voltage Vclamp, and the voltage of the input voltage bus VCC. Moreover, in this embodiment, the load 200 is assumed to be an inductive load as an example.

In some embodiments, the clamping voltage Vclamp may be chosen to be close to the limit of the safe operating area (SOA) of the first switch transistor Q1, in order to minimize the impact on the normal operation of the low-side switch circuit 100. For this reason, when the voltage across the clamping branch 30 exceeds the clamping voltage Vclamp, a risk of overvoltage on the first switch transistor Q1 may occur. FIG. 15 shows, as an example, waveforms during the turn-off process of the first switch transistor Q1 in the case of a short circuit in the load 200.. At time t30, the first switch transistor Q1 is in the on-state, and the voltage VO1 at the output terminal VOUT of the low-side switch circuit 100 is 0. At time t31, a short circuit occurs in the load 200, and due to the parasitic inductance in the connection path to the load, the current IQ1 flowing through the first switch transistor Q1 increases linearly, with the rate of current increase being VCC/Lout, where Lout is the inductance of the parasitic inductance in the path to the load 200. At time t32, the first detection signal (i.e., the voltage VSNS representing the current IQ1 through the first switch transistor Q1) reaches the second preset voltage threshold VREFH (representing the current limit). The first enable signal EN1/second enable signal EN2 are triggered and flips to a high level, enabling both the first pull-down branch 10 and the second pull-down branch 20 to start discharging the gate of the first switch transistor Q1. The current in the first pull-down branch 10 (i.e., the first pull-down current IA1) and the current in the second pull-down branch 20 (i.e., the second pull-down current IA2) are added together, as shown by current IC1. The first switch transistor Q1 is controlled to begin turning off, and by time t33, the first switch transistor Q1 has fully turned off, with the current IQ1 reaching its peak. As the first switch transistor Q1 completes its turn-off, the current stored in the parasitic inductance LL starts pushing the voltage VO1 at the output terminal VOUT above the clamping voltage Vclamp of the clamping branch 30. At this time, the clamping branch 30 conducts due to revers breakdown, and the first pull-down branch 10 and the second pull-down branch 20 discharge the parasitic inductance LL, with the discharge current also being current IC1, and the current IQ1 starts to decrease. Since the clamping voltage Vclamp of the clamping branch 30 is determined by the voltage drop across the clamping branch 30 when the first pull-down current IA1 flows through it, when current IC1 flows through the clamping branch 30, the voltage VO1 at the output terminal VOUT reaches Vclamp + ΔV due to the higher pull-down current following through the clamping branch 30. This also means that the first switch transistor Q1 is exposed to a voltage higher than the clamping voltage Vclamp of the clamping branch 30, creating an overvoltage risk. At time t35, as the discharge of the parasitic inductance LL is completed, the voltage VSNS reaches the third preset voltage threshold VREFL, and the first enable signal EN1/second enable signal EN2 switch to a low level, causing the first pull-down branch 10 and the second pull-down branch 20 to deactivate. The voltage VO1 at the output terminal VOUT also starts to drop rapidly from time t35, eventually stabilizing, after several oscillations, to the voltage of the input voltage bus VCC.

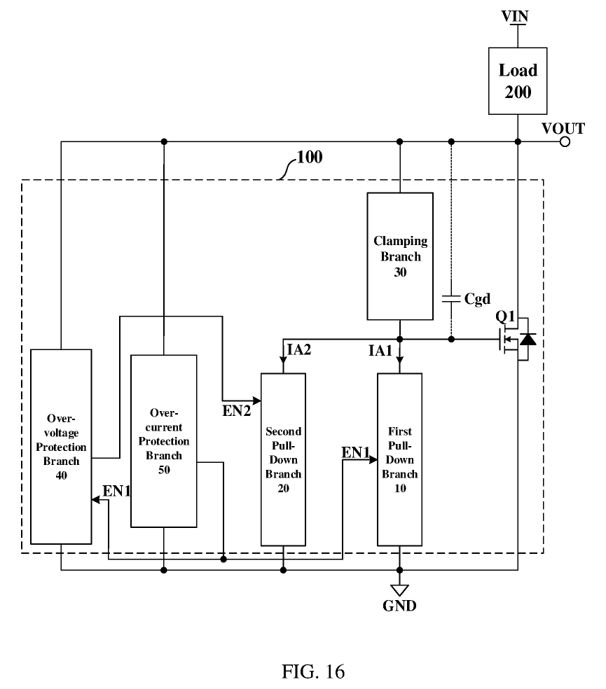

In some embodiments, as shown in FIG. 16, an overvoltage protection branch 40 may also be added to the structure shown in FIG. 12. The overvoltage protection branch 40 is connected between the output terminal VOUT and the ground GND, and is connected to the second pull-down branch 20 and the overcurrent protection branch 50.

In some embodiments, the overvoltage protection branch 40 is configured to generate a first indication signal S1 based on the voltage VO1 at the output terminal VOUT and output the second enable signal EN2. The overvoltage protection branch 40 may also be configured to output the second enable signal EN2 based on the first indication signal S1 and the first enable signal EN1 that is output by the overcurrent protection branch 50. When the voltage VO1 at the output terminal VOUT is greater than or equal to the first preset voltage threshold, the second enable signal EN2 and the first indication signal S1 are the same. The second pull-down branch 20 is configured to deactivate in response to the first indication signal S1 when the voltage VO1 at the output terminal VOUT is greater than or equal to the first preset voltage threshold.

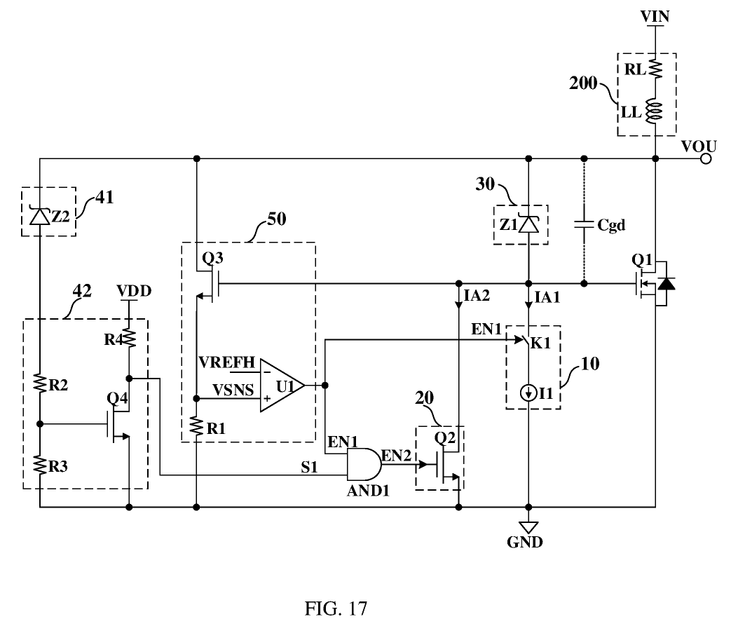

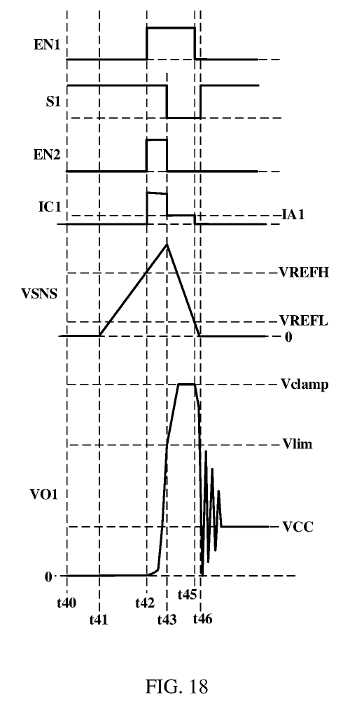

FIG. 17 is a schematic diagram of an example for implementing the circuit of FIG. 16. The overvoltage protection branch 40 includes a circuit 41 and a circuit 42. It is understood that the specific circuit structure of the overvoltage protection branch 40 shown in FIG. 17 is the same as the circuit structure of the overvoltage protection branch 40 shown in FIG. 9, and both generate the first indication signal S1 based on the voltage at the output terminal VOUT and both output the second enable signal EN2. When the voltage at the output terminal VOUT is greater than or equal to the first preset voltage threshold, the second enable signal EN2 and the first indication signal EN1 are the same signal. The second pull-down branch 20 is further configured to deactivate in response to the first indication signal S1 when the voltage at the output terminal VOUT is greater than or equal to the first preset voltage threshold. The waveforms of signals of the circuit in FIG. 17, i.e., the circuit formed with addition of the overvoltage protection branch 40 to the circuit shown in FIG. 14, are shown in FIG. 18.

Referring to FIG. 18, FIG. 18 exemplarily illustrates waveforms of the signals in the circuit structure shown in FIG. 17. In FIG.18, the horizontal axis represents time, and FIG. 18 shows, the along the vertical axis from top to bottom, waveforms of the first enable signal EN1, the first indication signal S1, the second enable signal EN2 output by the AND gate AND1, current IC1, the voltage VSNS at the non-inverting input terminal of the first comparator U1, and the voltage VO1 at the output terminal VOUT, respectively. FIG. 18 also shows, in dashed lines parallel to the horizontal axis from top to bottom, the first pull-down current IA1, the second preset voltage threshold VREFH, the third preset voltage threshold VREFL, the reference for the first detection signal VSNS being 0V, the clamping voltage Vclamp, the first preset voltage threshold Vlim, and the voltage of the input voltage bus VCC. Moreover, in this embodiment, the load 200 is an inductive load as an example.

As shown, before time t43, the first indication signal S1 remains at the high level, and the second enable signal EN2 output by the AND gate AND1 is the same as the first enable signal EN1. At time t43, the voltage VO1 at the output terminal VOUT rises to the first preset voltage threshold Vlim. At this time, the Zener diode Z2 conducts through reverse breakdown, and the fourth switch transistor Q4 is driven to conduct, causing the first indication signal S1 to switch to the low level, thereby disabling the second pull-down branch 20, so that the second pull-down branch 20 remains deactivated. It can be seen that at time t43, the total pull-down current IC1 is reduced because the second pull-down branch 20 is disabled. After the first switch transistor Q1 completes its turn-off (after time t43), the voltage VO1 at the output terminal VOUT rises above the first preset voltage threshold Vlim, the first indication signal S1 flips to the low level due to the reverse breakdown of the Zener diode Z2, and the control signal for the second pull-down branch 20 (i.e., the second enable signal EN2) flips to the low level too, dynamically disabling the second pull-down branch 20. This avoids the situation where the voltage VO1 at the output terminal VOUT exceeds the clamping voltage Vclamp, as seen in FIG. 15. At time t45, the voltage of first detection signal VSNS representing the current IQ1 flowing through the first switch transistor Q1 drops to the third preset voltage threshold VREFL, indicating that the discharge of the parasitic inductance LL is nearing completion, and the first enable signal EN1 switches to the low level. As a result, the first pull-down branch 10 and the second pull-down branch 20 are both deactivated. Subsequently, the voltage VO1 at the output terminal VOUT begins to drop. By time t46, the voltage VO1 at the output terminal VOUT has dropped below the first preset voltage threshold Vlim, the Zener diode Z2 stops conducting (reverse breakdown), the fourth switch transistor Q4 turns off, and the first indication signal S1 returns to the high level.

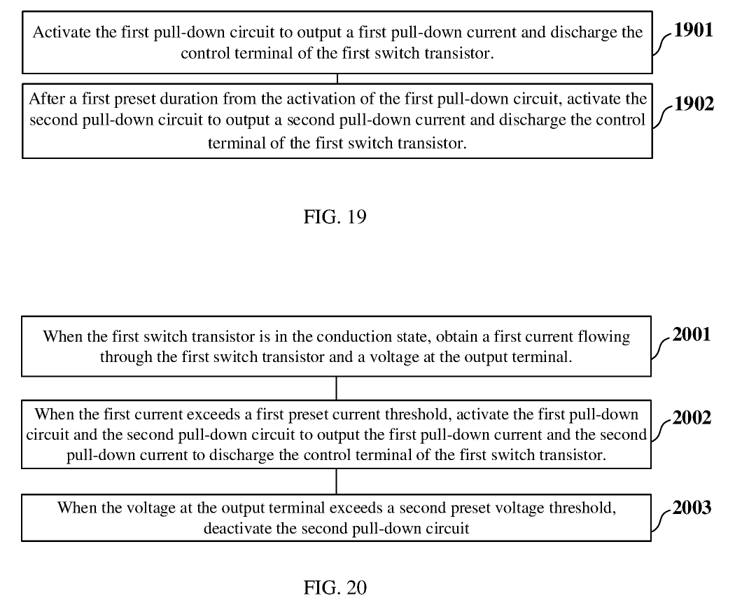

Referring to FIG. 19, FIG. 19 is a flowchart of a first control method for a low-side switch circuit provided in embodiments of the present application. The low-side switch circuit comprises a first switch transistor, a first pull-down branch, and a second pull-down branch. The two non-controlling terminals of the first switch transistor are connected between an output terminal of the low-side switch circuit and ground. The output terminal is connected to an input voltage bus through a load. Both the first pull-down branch and the second pull-down branch are connected between the control terminal of the first switch transistor and the ground. In some embodiments, the low-side switch circuit described herein may be implemented using one of the structures shown in FIGS. 1-5, FIGS. 7-9, FIGS. 12-14, and FIGS. 16-17. The specific implementation process has been described in detail in the foregoing embodiments and will not be repeated here. As shown in FIG. 19, the first control method comprises the following steps 1901 and 1902.

From the embodiments shown in FIG. 18 and FIG. 17, it can be seen that in the case of a short circuit in the load 200, by configuring the first pull-down branch 10 to deactivate in response to the first enable signal EN1 later than the second pull-down branch 20 which deactivates in response to the second enable signal EN2 (i.e., the second pull-down branch 20 deactivates in response to the second enable signal EN2 earlier than the first pull-down branch 10 deactivating in response to the first enable signal EN1), the risk of the first switch transistor Q1 in the low-side switch circuit 100 being damaged due to overvoltage can be effectively reduced.

Step 1901: Activate the first pull-down circuit to output a first pull-down current and discharge the control terminal of the first switch transistor.

Step 1902: After a first preset duration from the activation of the first pull-down circuit, activate the second pull-down circuit to output a second pull-down current and discharge the control terminal of the first switch transistor.

It should be understood that the specific control of the low-side switch circuit and the beneficial effects generated in the method embodiments can be referenced from the corresponding descriptions in the embodiments of the low-side switch circuit described above. For brevity, these will not be repeated here.

Please refer to FIG. 20. FIG. 20 is a flowchart of a second control method for a low-side switch circuit provided in embodiments of this application. The low-side switch circuit comprises a first switch transistor, a first pull-down circuit, and a second pull-down circuit. The two non-controlling terminals of the first switch transistor are connected between an output terminal and ground, with the output terminal connected to an input voltage bus through a load. Both the first pull-down circuit and the second pull-down circuit are connected between the control terminal of the first switch transistor and the ground. In some embodiments, the low-side switch circuit here may be realized through one of the structures shown in FIGS. 1-5, FIGS. 7-9, FIGS. 12-14, and FIGS. 16-17. The specific implementation process has been described in detail in the previous embodiments and will not be repeated here. As shown in FIG. 20, the second control method comprises the following steps 2001, 2002 and 2003.

Step 2001: When the first switch transistor is in the conduction state, obtain a first current flowing through the first switch transistor and a voltage at the output terminal.

Step 2002: When the first current exceeds a first preset current threshold, activate the first pull-down circuit and the second pull-down circuit to output the first pull-down current and the second pull-down current to discharge the control terminal of the first switch transistor.

Step 2003: When the voltage at the output terminal exceeds a second preset voltage threshold, deactivate the second pull-down circuit.

In some embodiments, the second control method further comprises the following steps: when the voltage at the output terminal is less than or equal to the second preset voltage threshold, and the first current increases to exceed the first preset current threshold, activate the first pull-down circuit and the second pull-down circuit. Subsequently, when the voltage at the output terminal exceeds the second preset voltage threshold, deactivate the second pull-down circuit. When the first current decreases to below a second preset current threshold, deactivate the first pull-down circuit and the second pull-down circuit, wherein the second preset current threshold is less than the first preset current threshold.

It should be understood that the specific control of the low-side switch circuit and the beneficial effects generated in the method embodiments can be referenced from the corresponding descriptions in the embodiments of the low-side switch circuit described above. For brevity, these will not be repeated here.

Embodiments of the present application also provide a low-side switch integrated circuit, which comprises one of the low-side switch circuits 100 described in the embodiments of this application.

Embodiments of the present application also provide an electronic device, which comprises a load and one of the low-side switch integrated circuit described in the embodiments of this application.

The above provides merely examples of embodiments of this application and is not intended to limit the scope of the present application. Any equivalent structure or equivalent process transformation based on the content of the present disclosure, or direct or indirect application of the present disclosure in other relevant technical fields, should be considered within the scope of this application.

The above embodiments are merely used to illustrate the technical solutions of this application and not to limit them. Based on the ideas of this application, the technical features in the above or different embodiments can be combined, and the steps can be implemented in various applicable orders. Persons of ordinary skill in the art should understand that they can still modify the technical solutions described in the aforementioned embodiments or make equivalent replacements for some technical features. These modifications or replacements do not deviate from the essence of the technical solutions of the embodiments of this application.

1. A low-side switch circuit, connected between a load and ground, with the load connected to an input voltage bus, the low-side switch circuit comprising:
a first switch transistor, wherein two non-controlling terminals of the first switch transistor are connected between an output terminal and the ground, and the output terminal is a terminal of the low-side switch circuit connected to the load;
a first pull-down branch, connected between a control terminal of the first switch transistor and the ground, wherein the first pull-down branch is configured to: activate or deactivate in response to a first enable signal, and when the first pull-down branch activates, generate a first pull-down current to discharge the control terminal of the first switch transistor; and
a second pull-down branch, connected between the control terminal of the first switch transistor and the ground, wherein the second pull-down branch is configured to activate or deactivate in response to a second enable signal, and when the second pull-down branch activates, generate a second pull-down current to discharge the control terminal of the first switch transistor; and
wherein the first pull-down branch activates in response to the first enable signal earlier than the second pull-down branch activating in response to the second enable signal, or the first pull-down branch deactivates in response to the first enable signal later than the second pull-down branch deactivating in response to the second enable signal.

2. The low-side switch circuit according to claim 1, wherein the first enable signal and a system enable signal of the low-side switch circuit are complementary signals, and the second enable signal is a delayed version of the first enable signal delayed by a first preset duration.

3. The low-side switch circuit according to claim 1, further comprising:
a clamping branch, connected between the output terminal and the control terminal of the first switch transistor, and configured to clamp a voltage between the output terminal and the control terminal of the first switch transistor to not exceed a first preset clamping voltage.

4. The low-side switch circuit according to claim 3, wherein,
the clamping branch comprises at least one diode, an anode of a first diode of the at least one diode is connected to the output terminal, and a cathode of a second diode of the at least one diode is connected to the control terminal of the first switch transistor; or
the clamping branch comprises at least one Zener diode, an anode of a first Zener diode of the at least one Zener diode is connected to the control terminal of the first switch transistor, and a cathode of a second Zener diode of the at least one Zener diode is connected to the output terminal.

5. The low-side switch circuit according to claim 1, wherein the first pull-down branch comprises a first switch and a first current source;
the first switch and the first current source are connected in series between the control terminal of the first switch transistor and the ground, and the first switch is controllably turned on or off by the first enable signal.

6. The low-side switch circuit according to claim 1, wherein the second pull-down branch comprises a second switch transistor;
a control terminal of the second switch transistor is configured to receive the second enable signal, and two non-controlling terminals of the second switch transistor are connected between the control terminal of the first switch transistor and the ground.

7. The low-side switch circuit according to claim 1, further comprising:
an overvoltage protection branch, connected between the output terminal and the ground, and connected to the second pull-down branch, wherein the overvoltage protection branch is configured to generate a first indication signal based on a voltage at the output terminal and generate the second enable signal; and
wherein the second pull-down branch is further configured to:
activate or deactivate in response to the second enable signal when the voltage at the output terminal is less than a first preset voltage threshold, and
remain deactivated in response to the first indication signal when the voltage at the output terminal is greater than or equal to the first preset voltage threshold.

8. The low-side switch circuit according to claim 7, wherein, when the voltage at the output terminal is greater than the first preset voltage threshold, the first indication signal is low, and when the voltage at the output terminal is less than the first preset voltage threshold, the first indication signal is high.

9. The low-side switch circuit according to claim 1, further comprising:
an overcurrent protection branch, connected to the output terminal, the first pull-down branch and the second pull-down branch, wherein the overcurrent protection branch is configured to: generate a first detection signal representing a current flowing through the first switch transistor when the first switch transistor is turned on, and based on the first detection signal, generate the first enable signal, and wherein, when the first switch transistor is on, the second enable signal is same as the first enable signal;
wherein the first pull-down branch is further configured to activate in response to the first enable signal when the first detection signal exceeds a first preset threshold; and
the second pull-down branch is further configured to activate in response to the second enable signal when the first detection signal exceeds the first preset threshold.

10. The low-side switch circuit according to claim 9, wherein the overcurrent protection branch comprises a third switch transistor, a first resistor, and a first comparator;
a control terminal of the third switch transistor is connected to the control terminal of the first switch transistor, and two non-controlling terminals of the third switch transistor are connected to the output terminal and a non-inverting input terminal of the first comparator, respectively;
the first resistor is connected between the non-inverting input terminal of the first comparator and the ground; and
the first comparator is configured to receive a second preset voltage threshold at its inverting input terminal, and outputs the first enable signal at its output terminal.

11. The low-side switch circuit according to claim 10, wherein the first comparator is a hysteresis comparator, and
when an input voltage at the non-inverting input terminal of the first comparator rises above the second preset voltage threshold, the first enable signal switches from low to high, and
when the input voltage at the non-inverting input terminal of the first comparator drops below a third preset voltage threshold, the first enable signal switches from high to low, wherein the third preset voltage threshold is lower than the second preset voltage threshold.

12. The low-side switch circuit according to claim 9, further comprising:
an overvoltage protection branch, connected between the output terminal and the ground, and connected to the second pull-down branch, wherein the overvoltage protection branch is configured to generate a first indication signal based on a voltage at the output terminal and generate the second enable signal;
wherein, when the voltage at the output terminal is greater than or equal to a first preset voltage threshold, the second enable signal is same as the first indication signal; and
the second pull-down branch is further configured to deactivate in response to the first indication signal when the voltage at the output terminal is greater than or equal to the first preset voltage threshold.

13. The low-side switch circuit according to claim 12, wherein the overvoltage protection branch comprises a clamping unit, a switching unit, and an AND gate;
the clamping unit is connected between the output terminal and the switching unit, the switching unit is connected to a first input terminal of the AND gate and is configured to output the first indication signal to the first input terminal of the AND gate; an output terminal of the AND gate is connected to the second pull-down branch, and a second input terminal of the AND gate receives a delayed version of the first enable signal or the first enable signal;
the clamping unit is configured to turn off when the voltage at the output terminal is less than the first preset voltage threshold, and to turn on when the voltage at the output terminal is greater than or equal to the first preset voltage threshold; and
the switching unit is configured to set the first indication signal to high when the clamping unit is off, and to set the first indication signal to low when the clamping unit is on.

14. The low-side switch circuit according to claim 13, wherein, the clamping unit comprises at least one second diode or at least one second Zener diode;
the clamping unit comprises at least one diode, an anode of a first diode of the at least one diode is connected to the output terminal, and a cathode of a second diode of the at least one diode is connected to the switching unit; or
the clamping unit comprises at least one Zener diode, an anode of a first Zener diode of the at least one Zener diode is connected to the switching unit, and a cathode of a second Zener diode of the at least one Zener diode is connected to the output terminal.

15. The low-side switch circuit according to claim 13, wherein the switching unit comprises a second resistor, a third resistor, a fourth resistor, and a fourth switch transistor;
the second resistor and the third resistor are connected in series between the clamping unit and the ground, a common node of the second resistor and the third resistor is connected to the control terminal of the fourth switch transistor, two non-controlling terminals of the fourth switch transistor are connected to the first input terminal of the AND gate and the ground respectively, and the fourth resistor is connected between a first power supply and the first input terminal of the AND gate.

16. A control method of a low-side switch circuit comprising a first switch transistor, a first pull-down branch and a second pull-down branch, wherein the control method comprises:
activating the first pull-down branch to generate a first pull-down current to discharge a control terminal of the first switch transistor, wherein the first switch transistor comprises two non-controlling terminals connected to an output terminal and ground, respectively, the output terminal is connected to an input voltage bus through a load, and the first pull-down branch and the second pull-down branch are connected between the control terminal of the first switch transistor and the ground; and
activating, after a first preset duration from a moment at which the first pull-down branch is activated, the second pull-down branch to generate a second pull-down current to discharge the control terminal of the first switch transistor.

17. A control method of a low-side switch circuit comprising a first switch transistor, a first pull-down branch and a second pull-down branch, wherein the control method comprises:
when the first switch transistor is in an on-state, obtaining a first current flowing through the first switch transistor and a voltage at an output terminal of the low-side switch circuit, wherein the first switch transistor comprises two non-controlling terminals connected to the output terminal and ground, respectively, the output terminal is connected to an input voltage bus through a load, and the first pull-down branch and the second pull-down branch are connected between a control terminal of the first switch transistor and the ground;
when the first current exceeds a first preset current threshold, activating the first pull-down branch and the second pull-down branch to generate a first pull-down current and a second pull-down current respectively, to discharge the control terminal of the first switch transistor; and
after activating the first pull-down branch and the second pull-down branch, and when the voltage at the output terminal exceeds a second preset voltage threshold, deactivating the second pull-down branch.

18. The control method according to claim 17, wherein further comprising:
when the voltage at the output terminal is less than or equal to the second preset voltage threshold, and the first current rises above the first preset current threshold, activating the first pull-down branch and the second pull-down branch;
thereafter, when the voltage at the output terminal exceeds the second preset voltage threshold, deactivating the second pull-down branch; and
when the first current decreases to below a second preset current threshold, deactivating both the first pull-down branch and the second pull-down branch, wherein the second preset current threshold is lower than the first preset current threshold.

19. A low-side switch integrated circuit, comprising the low-side switch circuit according to claim 1.

20. An electronic device, comprising the low-side switch integrated circuit according to claim 19 and the load.
